(19) United States
(12) Patent Application Publication
(10) Pub. No.: US 2026/0190792 A1
(43) Pub. Date: Jul. 2, 2026

(54) Display Module, Electronic Device, And Method Of Manufacturing Same

(71) Applicant: Samsung Display Co., Ltd., Yongin-si (KR)

(72) Inventors: Myoungjin Park, Yongin-si (KR); Seunguk Noh, Yongin-si (KR)

(73) Assignee: Samsung Display Co., Ltd., Yongin-si (KR)

(21) Appl. No.: 19/381,112

(22) Filed: Nov. 6, 2025

(30) Foreign Application Priority Data
Dec. 31, 2024 (KR) 10-2024-0202482

(51) Int. Cl. H10K 59/80; H10K 50/115; H10K 50/15; H10K 50/16; H10K 59/12; H10K 59/122

(52) U.S. Cl. CPC H10K 59/8731; H10K 50/115; H10K 50/156; H10K 50/166; H10K 59/1201; H10K 59/122

(57) ABSTRACT

Disclosed is a display module including a base layer and a display element layer. A pixel definition layer is disposed on the base layer and defines pixel openings. A first light emitting element, a second light emitting element, and the third light emitting element are arranged in the pixel openings. An encapsulation layer including a first encapsulation portion is disposed on the pixel definition layer, overlapping the first light emitting element, and not overlapping the second light emitting element and the third light emitting element. A second encapsulation portion is disposed on the first encapsulation portion and overlapping the first light emitting element, the second light emitting element, and the third light emitting element.

### CROSS-REFERENCE TO RELATED APPLICATIONS

This application claims priority under 35 U.S.C. § 119 to Korean Patent Application No. 10-2024-0202482 filed on Dec. 31, 2024, the disclosures of which are incorporated by reference herein in their entireties.

### TECHNICAL FIELD

The present disclosure relates to a display device and an electronic device that incorporates such display device.

### BACKGROUND

Embodiments of the present disclosure described herein relate to a display module and an electronic device including the display module, and more particularly, relate to a display module including a quantum dot, an electronic device including the display module, and a method of manufacturing the electronic device.

Various display modules for providing image information in multimedia devices such as televisions, mobile phones, tablet computers, navigation systems, and game consoles have been developed.

In particular, to improve a display quality of the display module, display elements using quantum dots as well as liquid crystal display elements and organic light-emitting elements have been developed.

While use of the above-mentioned and other similar varieties of display devices is generally desirable, existing devices may suffer from inadequate brightness, lifetime, and reliability of the display module. Accordingly, a need exists for display devices with brightness, lifetime, and reliability.

### BRIEF SUMMARY

Some examples of the present disclosure provide a display module having improved reliability. Further, additional examples of the present disclosure also provide an electronic device having improved reliability and a method of manufacturing an electronic device.

According to one example, a display module includes a base layer and a display element layer. A pixel definition layer may be disposed on the base layer and in which a plurality of pixel openings are defined. A first light emitting element, a second light emitting element, and a third light emitting element are arranged in the plurality of pixel openings. An encapsulation layer including a first encapsulation portion is disposed on the pixel definition layer, overlapping the first light emitting element, and not overlapping the second light emitting element and the third light emitting element. A second encapsulation portion is disposed on the first encapsulation portion and overlapping the first light emitting element, the second light emitting element, and the third light emitting element.

The first light emitting element may include a first light emitting layer including an organic light emitting material, the second light emitting element may include a second light emitting layer including a first quantum dot, and the third light emitting element may include a third light emitting layer including a second quantum dot different from the first quantum dot.

The display element layer may further include a capping layer covering the first encapsulation portion, the second light emitting element, and the third light emitting element and a resin layer disposed on the capping layer and including an acidic resin material.

The display element layer may further include a capping layer covering the first encapsulation portion, the second light emitting element, and the third light emitting element and including an acidic resin material.

The first encapsulation portion may include a (1-1)^{th} inorganic encapsulation layer, a first organic encapsulation layer, and a (1-2)^{th} inorganic encapsulation layer, and the second encapsulation portion may include a (2-1)^{th} inorganic encapsulation layer, a second organic encapsulation layer, and a (2-2)^{th} inorganic encapsulation layer.

The second organic encapsulation layer may include an acidic resin material.

The acidic resin material may include any one of a methacrylic acid, an acrylic acid, or a citric acid.

The first light emitting element may provide a blue light, and the second light emitting element may provide a red light.

The third light emitting element may provide a green light.

The second encapsulation portion may include glass.

The first light emitting element may include a first hole transport layer, a first light emitting layer, and a first electron transport layer that are all sequentially laminated in a direction away from the base layer. The second light emitting element may include a second hole transport layer, a second light emitting layer, and a second electron transport layer that are all sequentially laminated in a direction away from the base layer. The third light emitting element may include a third hole transport layer, a third light emitting layer, and a third electron transport layer that are all sequentially laminated in a direction away from the base layer.

The first light emitting element may include a first electrode, a first electron transport layer, a first light emitting layer, a hole transport layer and a (2-1)^{th} electrode that are all sequentially laminated in a direction away from the base layer. The second light emitting element may include the first electrode, a second electron transport layer, a second light emitting layer, the hole transport layer and a (2-2)^{th} electrode that are all sequentially laminated in a direction away from the base layer. The third light emitting element may include the first electrode, a third electron transport layer, a third light emitting layer, the hole transport layer and the (2-2)^{th} electrode that are all sequentially laminated in a direction away from the base layer. A portion of the first encapsulation portion may cover the pixel definition layer, and the other portion of the first encapsulation portion may cover the first light emitting element.

At least a portion of the first encapsulation portion may be curved in a direction toward the base layer.

The first light emitting element may include a first electrode, a first light emitting layer, and a second electrode that are sequentially arranged in a direction away from the base layer, the first encapsulation portion and the pixel definition layer may be spaced apart from each other with the second electrode interposed therebetween, and a planar area of the first encapsulation portion may be larger than a planar area of the first light emitting layer.

According to some examples, an electronic device includes a display module including a base layer and a display element layer. A pixel definition layer which is disposed on the base layer that defines pixel openings. A first light emitting element, a second light emitting element, and the third light emitting element are arranged in the pixel openings. An encapsulation layer includes a first encapsulation portion disposed on the pixel definition layer, overlapping the first light emitting element, and not overlapping the second light emitting element and the third light emitting element. A second encapsulation portion is disposed on the first encapsulation portion and overlapping the first light emitting element, the second light emitting element, and the third light emitting element. A housing provides a base space in which the display module is to be disposed, and an electronic module provides an electrical signal to the display module.

According to some examples, a method of manufacturing an electronic device includes providing a preliminary display module including a base layer and a display element layer. A pixel definition layer is disposed on the base layer defines pixel openings. A first light emitting element, a second light emitting element, and a third light emitting element are arranged in the pixel openings. A first preliminary encapsulation portion is formed by overlapping the first light emitting element, the second light emitting element, and the third light emitting element on the pixel definition layer. A first encapsulation portion is formed by removing a portion of the first preliminary encapsulation portion, which overlaps the second light emitting element and the third light emitting element. A second encapsulation portion is formed by overlapping the first light emitting element, the second light emitting element, and the third light emitting element and covering the first encapsulation portion.

The forming of the first encapsulation portion may include performing a photoresist process on the first preliminary encapsulation portion.

The forming of the second encapsulation portion may include forming a (2-1)^{th} inorganic encapsulation layer that overlaps the first light emitting element, the second light emitting element, and the third light emitting element. A second organic encapsulation layer is formed on the (2-1)^{th} inorganic encapsulation layer, and fa (2-2)^{th} inorganic encapsulation layer is formed on the second organic encapsulation layer. The second organic encapsulation layer may include an acidic resin material.

The method may further include, after the forming of the first encapsulation portion, forming a capping layer covering the first encapsulation portion, the pixel definition layer, the second light emitting element, and the third light emitting element. The capping layer may include an acidic resin material.

The method may further include, after the forming of the first encapsulation portion, forming a capping layer covering the first encapsulation portion, the pixel definition layer, the second light emitting element, and the third light emitting element and forming a resin layer including an acidic resin material on the capping layer.

The second encapsulation portion may be provided as a glass substrate, the first light emitting element may be provided as an organic light emitting element, and the second light emitting element and the third light emitting element may be provided as quantum dot light emitting elements.

### BRIEF DESCRIPTION OF THE FIGURES

The above and other objects and features of the present disclosure will become apparent by reading the following detailed description of non-limiting embodiments thereof, and with reference to the accompanying drawings, in which:

FIG. 1 is a block diagram of an electronic device according to the present disclosure;

FIG. 2 is a schematic view of examples of the electronic device according to FIG. 1;

FIG. 3 is a perspective view of the electronic device according to one embodiment of the present disclosure;

FIG. 4 is an exploded perspective view of the electronic device according to FIG. 3;

FIG. 5 is a cross-sectional view of a display module along line I-I′ of FIG. 4;

FIG. 6 is a plan view of a display module according to an embodiment of the present disclosure.

FIG. 7 is a cross-sectional view of the display module along line II-II′ of FIG. 6;

FIG. 8 is an enlarged view of area AA′ of FIG. 7;

FIG. 9 is an enlarged view of area BB′ of FIG. 7;

FIG. 10A is an enlarged cross-sectional view of the display module according to an embodiment of the present disclosure;

FIG. 10B is an enlarged cross-sectional view of the display module according to an embodiment of the present disclosure;

FIG. 11 is a flowchart of a method of manufacturing an electronic device according to an embodiment of the present disclosure; and

FIGS. 12 to 16 are cross-sectional views of a display module that illustrates operations of the method of manufacturing an electronic device according to an embodiment of the present disclosure.

### DETAILED DESCRIPTION

In the specification, the expression that a first component (or area, layer, part, portion, etc.) is “disposed on”, “connected with” or “coupled to” a second component means that the first component is directly disposed on and/or connected with or coupled to the second component or means that a third component is interposed therebetween.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first”, “second”, etc. may be used to describe various components, the components should not be limited by the terms. The terms are used only to distinguish one component, one part, one area, one layer or one portion from another component, another part, another area, another layer or another portion. For example, without departing from the scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

Hereinafter, examples of embodiment of the present disclosure will be described with reference to the accompanying drawings. Configurations that function substantially the same between embodiments are given the same drawing designation and repeated description is omitted.

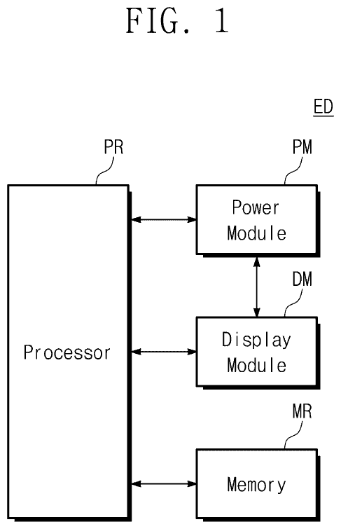

FIG. 1 is a block diagram of an electronic device according to the present disclosure.

The electronic device according to the present disclosure may be provided in various forms. The electronic device according to the present disclosure may further include a module or device having another additional function.

Referring to FIG. 1, an electronic device ED according to an embodiment may include a display module DM, a processor PR, a memory MR, and a power module PM.

The processor PR may include, but is not limited to, at least one of a central processing unit (CPU), an application processor (AP), a graphic processing unit (GPU), a communication processor (CP), an image signal processor (ISP), or a controller, and any combination thereof.

Data information required for operating the processor PR or the display module DM may be stored in the memory MR. When the processor PR executes an application stored in the memory MR, an image data signal and/or an input control signal may be transmitted to the display module DM, and the display module DM may process the received signal and output image information through a display screen.

The power module PM may include a power supply module such as, but not limited to, a power adapter or a battery device and a power conversion module that converts power supplied by the power supply module to generate power required for operating the electronic device ED.

Some of individual modules functionally included in one module may be included inside the display module DM, and the other thereof may be provided inside the electronic device ED separately from the display module DM.

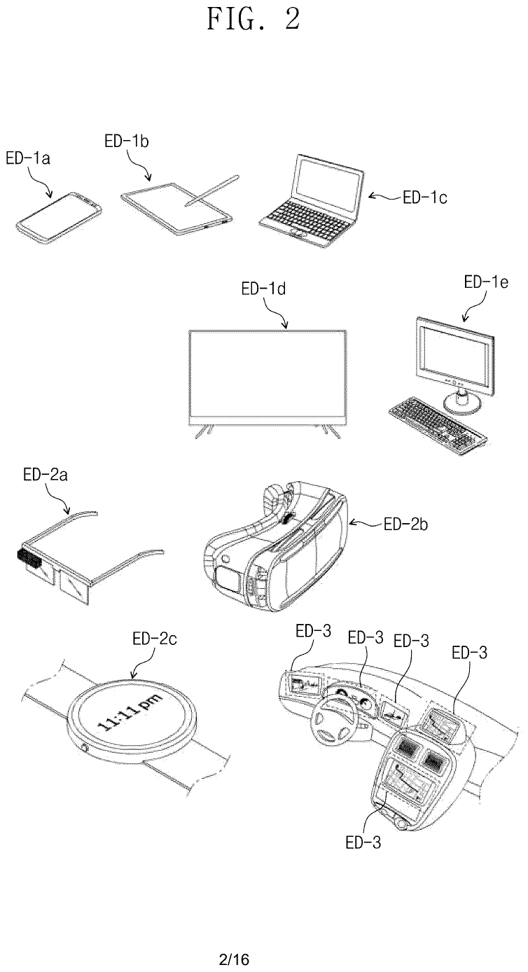

FIG. 2 is a schematic view of an electronic device according to an embodiment.

Referring to FIG. 2, the electronic device according to an embodiment may be an image display electronic device such as a smart phone ED-1a, a tablet PC ED-1b, a laptop ED-1c, a TV ED-1d, and a desk monitor ED-1e, a wearable electronic device including a display module such as smart glasses ED-2a, a head mounted display ED-2b, and a smart watch ED-2c, and a vehicle electronic device ED-3 including a display module such as an instrument panel, a center fascia, a center information display (CID) disposed on a dashboard, and a room mirror display of a vehicle.

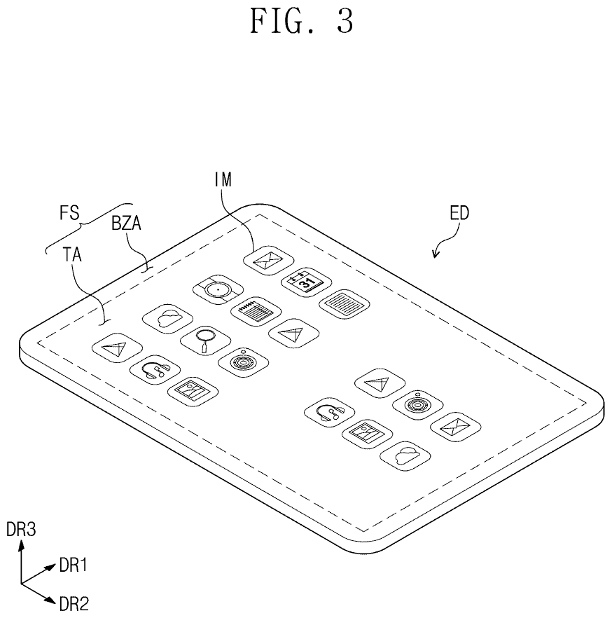

FIG. 3 is a perspective view of the electronic device according to an embodiment of the present disclosure that may include any of the electronic devices shown in FIG. 2. A transmissive area TA and a bezel area BZA are shown. Also shown in FIG. 3 is an image IM. TA, IM, and BZA are on a display surface FS. These areas are further explained in detail herein.

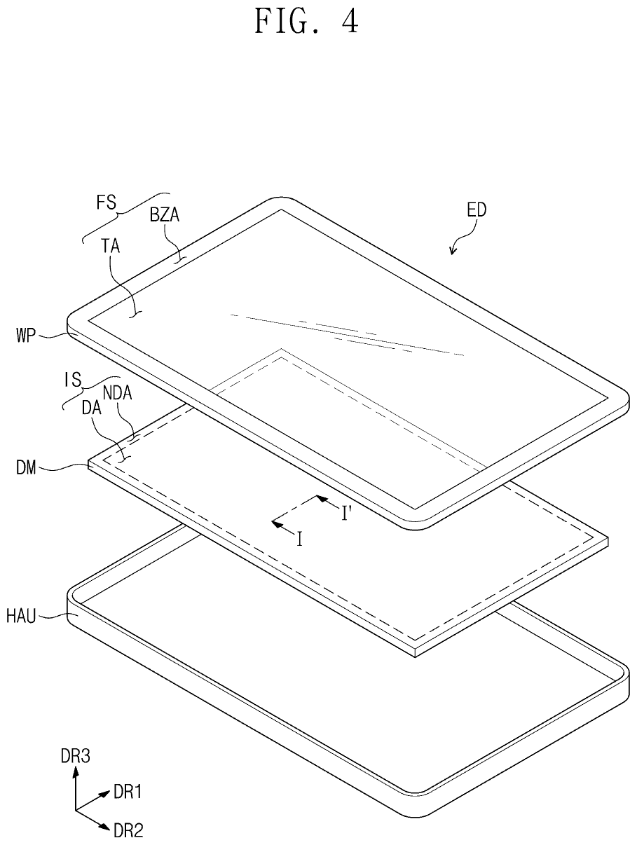

FIG. 4 is an exploded perspective view of the electronic device according to an embodiment of the present disclosure. In one example, the electronic device ED may have a rectangular shape having short sides extending in a first direction DR1 and long sides extending in a second direction DR2 on a plane. However, an embodiment of the present disclosure is not limited thereto, and the electronic device ED may have various shapes such as a circular shape and a polygonal shape.

The electronic device ED may display an image IM in a third direction DR3 through a display surface FS parallel to a surface defined by the first direction DR1 and the second direction DR2. The third direction DR3 may be substantially parallel to a normal direction of the display surface FS. The display surface FS on which the image IM is displayed may correspond to a front surface of the electronic device ED. The image IM may include a still image as well as a dynamic image. FIG. 3 illustrates icon images as an example of the image IM.

In one example, front surfaces (or upper surfaces) and rear surfaces (or lower surfaces) of members or units may be defined based on a direction in which the image IM is displayed. The front surface and the rear surface may be opposite to each other in the third direction DR3 and a normal direction of the front surface and the rear surface may be parallel to the third direction DR3. A separation distance between the front surface and the rear surface defined in the third direction DR3 may correspond to a thickness of the member (or the unit).

In the specification, the wording “on a plane” may be defined as a state of being viewed from the third direction DR3. In the specification, the wording “on a cross section” may be defined as a state of being viewed in the first direction DR1 or the second direction DR2. Meanwhile, directions indicated by the first direction DR1, the second direction DR2, and the third direction DR3 are relative concepts and may be changed to other directions.

In the electronic device ED, the display surface FS, on which the image IM is displayed, may correspond to the front surface of the electronic device ED and may correspond to a front surface FS of a window WP (see FIG. 4). Hereinafter, the same reference numeral or reference letters will be used for the display surface and the front surface of the electronic device ED and the front surface of the window WP. Although not illustrated in the drawings, the electronic device ED may include, for example, a foldable display device including a folding area and a non-folding area, or a bending display device including at least one bending part.

Referring to FIG. 4, the electronic device ED according to an embodiment may include the window WP, the display module DM, and a housing HAU.

The window WP may include an optically transparent insulating material. The window WP may include a transmissive area TA and a bezel area BZA. A user may visually recognize an image provided through the transmissive area TA corresponding to the front surface FS of the window WP.

The transmissive area TA may be an optically transparent area. The bezel area BZA may be an area having a relatively low light transmittance as compared to the transmissive area TA. The bezel area BZA may have a predetermined color. The bezel area BZA may be adjacent to the transmissive area TA and surround the transmissive area TA. The bezel area BZA may define a shape of the transmissive area TA. However, an embodiment is not limited to the illustration, the bezel area BZA may be disposed adjacent to only one side of the transmissive area TA, and a portion thereof may be omitted.

It is illustrated in FIGS. 3 and 4 that the transmissive area TA has a quadrangular shape. However, this is illustrated by way of example, the transmissive area TA may have various shapes, and the present disclosure is not limited to such an example.

The display module DM may be disposed under the window WP. The display module DM may be a component that substantially generates the image IM. The image IM generated by the display module DM is displayed on a display surface IS and is visually recognized by the user from the outside through the transmissive area TA.

The display module DM includes a display area DA and a non-display area NDA. The display area DA may be an area that is activated according to an electric signal. The non-display area NDA may be an area covered by the bezel area BZA. The non-display area NDA is adjacent to the display area DA. The non-display area NDA may surround the display area DA.

The housing HAU may accommodate the display module DM. The housing HAU may provide a base space in which the display module DM is to be disposed. The housing HAU may be disposed to cover the display module DM so that an upper surface, which is the display surface IS of the electronic device ED, is exposed. The housing HAU may cover a side surface and a bottom surface of the display module DM and may expose the entire upper surface. However, the housing is not limited thereto, and the housing HAU may cover a portion of the upper surface as well as the side surface and the bottom surface of the display module DM.

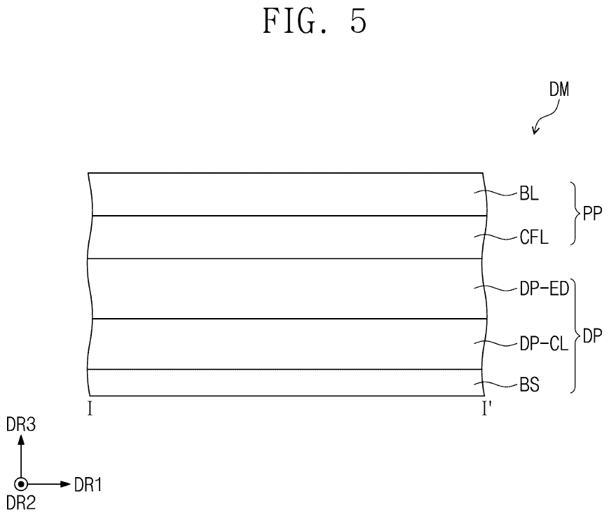

FIG. 5 is a cross-sectional view of a display module along line I-I′ of FIG. 4. In one example, the display module DM may include a display panel DP and an optical panel PP disposed on the display panel DP.

The display panel DP may be a light emitting display panel. The display module DM may include a base layer BS, a circuit element layer DP-CL disposed on the base layer BS, and a display element layer DP-ED disposed on the circuit element layer DP-CL.

The base layer BS may be disposed at a lowermost side of the display module DM and provide a base surface on which a component of the display module DM is to be disposed. The optical panel PP may be disposed on the display panel DP. The optical panel PP may include a base substrate BL and a light control layer CFL disposed under the base substrate BL.

The circuit element layer DP-CL may be disposed on the base layer BS. The circuit element layer DP-CL may include a plurality of insulating layers and a circuit element. For example, the circuit element layer DP-CL may include a semiconductor pattern such, but not limited to, as a transistor.

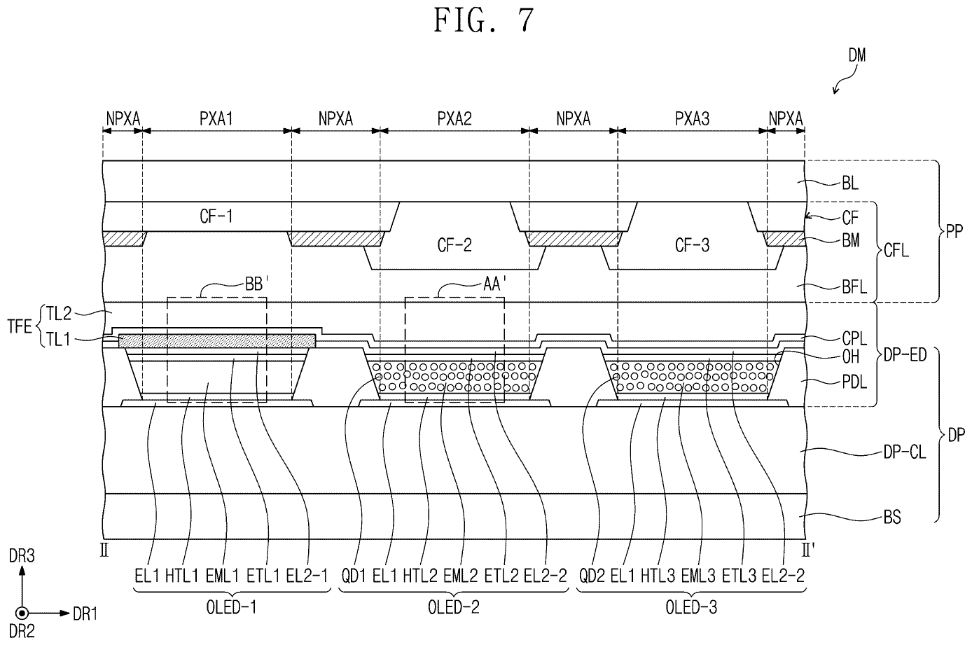

The display element layer DP-ED may be disposed on the circuit element layer DP-CL. The display element layer DP-ED may include a pixel definition layer PDL (see FIG. 7), light emitting elements OLED-1, OLED-2, and OLED-3 (see FIG. 7), and an encapsulation layer TFE (see FIG. 7).

The display panel DP according to the present disclosure may include both a “quantum dot electroluminescence element” and an “organic electroluminescence element” while reliability thereof may be improved. This will be described further below.

Again, the optical panel PP may be disposed on the display panel DP. The optical panel PP may include a base substrate BL and a light control layer CFL disposed under the base substrate BL. However, the present disclosure is not limited thereto, and in one example, the optical panel PP may be omitted or may be laminated on the display panel DP.

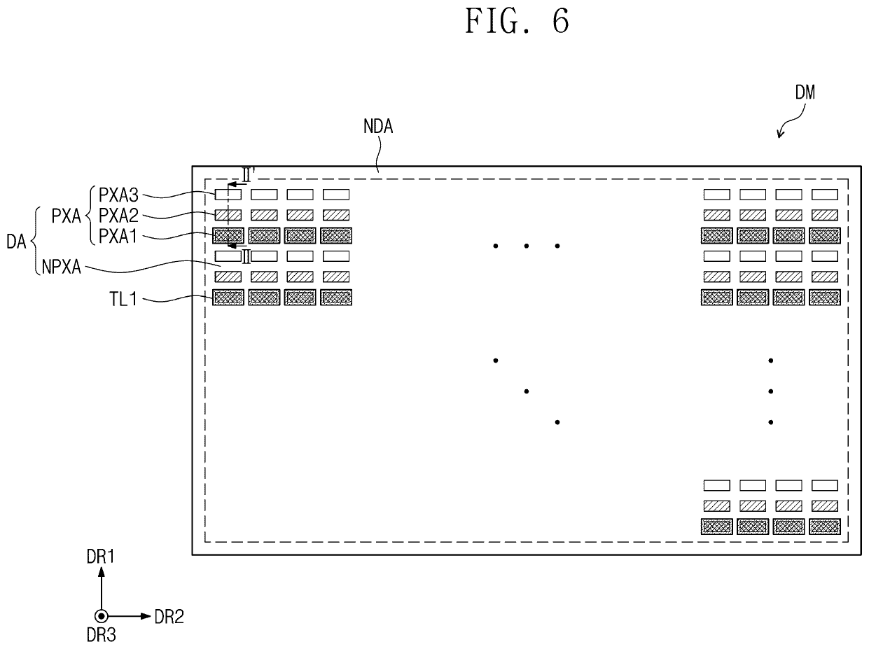

FIG. 6 is a plan view of the display module according to an embodiment of the present disclosure.

Referring to FIG. 6, the display area DA may include a light emitting area PXA and a peripheral area NPXA.

The light emitting area PXA may be defined as an area that emits a light in the display area DA. The light emitting areas PXA may be arranged in a predetermined rule within the display area DA. For example, the light emitting areas PXA may be arranged in the first direction DR1 and the second direction DR2.

One light emitting area PXA may include a first light emitting area PXA1, a second light emitting area PXA2, and a third light emitting area PXA3 spaced apart from each other in the first direction DR1. The first light emitting area PXA1, the second light emitting area PXA2, and the third light emitting area PXA3 may be all sequentially arranged in the first direction DR1 inside the one light emitting area PXA.

The first light emitting areas PXA1, the second light emitting areas PXA2, and the third light emitting areas PXA3 may all be aligned in the second direction DR2. The first light emitting area PXA1, the second light emitting area PXA2, and the third light emitting area PXA3 may be alternately arranged in the first direction DR1.

In the display module DM according to an embodiment, the light emitting areas PXA1, PXA2, and PXA3 may be arranged in a “strip shape.” However, an arrangement form of the light emitting areas PXA1, PXA2, and PXA3 is not limited to that illustrated in FIG. 6. The arrangement form of the light emitting areas PXA1, PXA2, and PXA3 may be variously combined and provided according to characteristics of display quality required by the display module DM. For example, the arrangement form of the light emitting areas PXA1, PXA2, and PXA3 may various subpixel matrix schemes used in electronic device displays or enhancing image quality by arranging pixels in a diamond pattern.

FIG. 6 illustrates that areas of the light emitting areas PXA1, PXA2, and PXA3 are identical/similar to each other, but an embodiment is not limited thereto. For example, the areas of the light emitting areas PXA1, PXA2, and PXA3 may be different from each other depending on a wavelength area of emitted light.

The peripheral area NPXA may be defined as an area of the display area DA except for the light emitting area PXA. The peripheral area NPXA may be disposed adjacent to the light emitting area PXA.

FIG. 7 is a cross-sectional view of the display module along line II-II′ of FIG. 6.

Referring to FIG. 7, the display module DM according to an embodiment may include the optical panel PP and the display panel DP disposed under the optical panel PP.

The optical panel PP may include the base substrate BL and the light control layer CFL disposed under the base substrate BL. The light control layer CFL may include a first color filter CF-1, a second color filter CF-2, and a third color filter CF-3 and a light shielding pattern BM. The first color filter CF-1, the second color filter CF-2, and the third color filter CF-3 may overlap the first light emitting area PXA1, the second light emitting area PXA2, and the third light emitting area PXA3, respectively. The first color filter CF-1, the second color filter CF-2, and the third color filter CF-3 may function to improve color purity of a light provided by the display module DM by transmitting light having a specific wavelength band and shielding a light having other wavelength bands.

The display panel DP may include the base layer BS, the circuit element layer DP-CL, and the display element layer DP-ED.

In an embodiment, the display element layer DP-ED may include the pixel definition layer PDL in which pixel openings OH are defined, a first light emitting element OLED-1, a second light emitting element OLED-2, and a third light emitting element OLED-3 arranged in the pixel openings OH, and the encapsulation layer TFE disposed on the pixel definition layer PDL.

The display module DM according to the present disclosure may include both the organic electroluminescence element and the quantum dot electroluminescence element. For example, the first light emitting element OLED-1 may be the organic electroluminescence element, and the second light emitting element OLED-2 and the third light emitting element OLED-3 may be the quantum dot electroluminescence elements. In the specification, the first light emitting element OLED-1 may also be expressed as an “organic light emitting element”, and the second light emitting element OLED-2 and the third light emitting element OLED-3 may also be expressed as “quantum dot light emitting elements.”

The first light emitting element OLED-1 may include a first electrode EL1, a first hole transport layer HTL1, a first light emitting layer EML1, a first electron transport layer ETL1, and a (2-1)^{th} electrode EL2-1, which are all sequentially laminated in a direction away from the base layer BS.

The second light emitting element OLED-2 may include the first electrode EL1, a second hole transport layer HTL2, a second light emitting layer EML2, a second electron transport layer ETL2, and a (2-2)^{th} electrode EL2-2, which are all sequentially laminated in a direction away from the base layer BS.

The third light emitting element OLED-3 may include the first electrode EL1, a third hole transport layer HTL3, a third light emitting layer EML3, a third electron transport layer ETL3, and the (2-2)^{th} electrode EL2-2, which are all sequentially laminated in a direction away from the base layer BS.

The (2-2)^{th} electrode EL2-2 may be provided as a common layer in the second light emitting element OLED-2 and the third light emitting element OLED-3.

In an embodiment, the first light emitting element OLED-1, the second light emitting element OLED-2, and the third light emitting element OLED-3 may provide lights having different wavelengths. For example, the first light emitting element OLED-1 may provide a blue light, the second light emitting element OLED-2 may provide a red light, and the third light emitting element OLED-3 may provide a green light.

The first light emitting layer EML1 may include an organic light emitting material, the second light emitting layer EML2 may include a first quantum dot QD1, and the third light emitting layer EML3 may include a second quantum dot QD2.

The first quantum dot QD1 and the second quantum dot QD2 may provide lights having different wavelengths.

The encapsulation layer TFE may be disposed on the display element layer DP-ED. The encapsulation layer TFE may include a first encapsulation portion TL1 and a second encapsulation portion TL2.

The first encapsulation portion TL1 may be disposed on the first light emitting element OLED-1. The first encapsulation portion TL1 may overlap the first light emitting element OLED-1 and may not overlap the second light emitting element OLED-2 and the third light emitting element OLED-3. The first encapsulation portion TL1 may prevent a phenomenon in which an “acidic resin material” caused by “positive aging”, which will be described below, damages the first light emitting element OLED-1.

The second encapsulation portion TL2 may be disposed on the first encapsulation portion TL1 and the pixel definition layer PDL. The second encapsulation portion TL2 may overlap the first light emitting element OLED-1, the second light emitting element OLED-2, and the third light emitting element OLED-3. The second encapsulation portion TL2 may prevent moisture/oxygen from permeating into the first light emitting element OLED-1, the second light emitting element OLED-2, and the third light emitting element OLED-3.

The display module DM according to the present disclosure may provide some light through the organic light emitting element OLED-1 and provide the remaining light through the quantum dot light emitting elements OLED-2 and OLED-3. For example, the display module DM according to the present disclosure may provide a blue light through the “organic light emitting element OLED-1” and provide a red light and a green light through the “quantum dot light emitting elements OLED-2 and OLED-3.”

In this case, when the quantum dot light emitting elements OLED-2 and OLED-3 undergo the “positive aging”, brightness, lifetime, and reliability of the quantum dot light emitting elements OLED-2 and OLED-3 may be improved.

The positive aging may refer to a process of permeating an “acidic resin material” into the electron transport layers ETL2 and ETL3 and the light emitting layers EML2 and EML3 included in the quantum dot light emitting elements OLED-2 and OLED-3. This will be described below.

However, when the acidic resin material permeates into the “organic light emitting element OLED-1, the first electron transport layer ETL1 or the first light emitting layer EML1 may be damaged, and thus brightness, lifetime, or reliability of the organic electroluminescence element OLED-1 may be reduced.

However, the display module DM according to an embodiment may improve the brightness, the lifetime, or the reliability of the “quantum dot light emitting element” using the positive aging and prevent the organic light emitting element from being damaged by the acidic resin material by selectively encapsulating the “organic light emitting element” through the first encapsulation portion TL1. Accordingly, brightness, lifetime, and reliability of the display module DM may be improved. That is, according to the present disclosure, a vulnerable layer may be protected from the “positive aging,” and a layer requiring positive aging may be easily exposed to the acidic resin material.

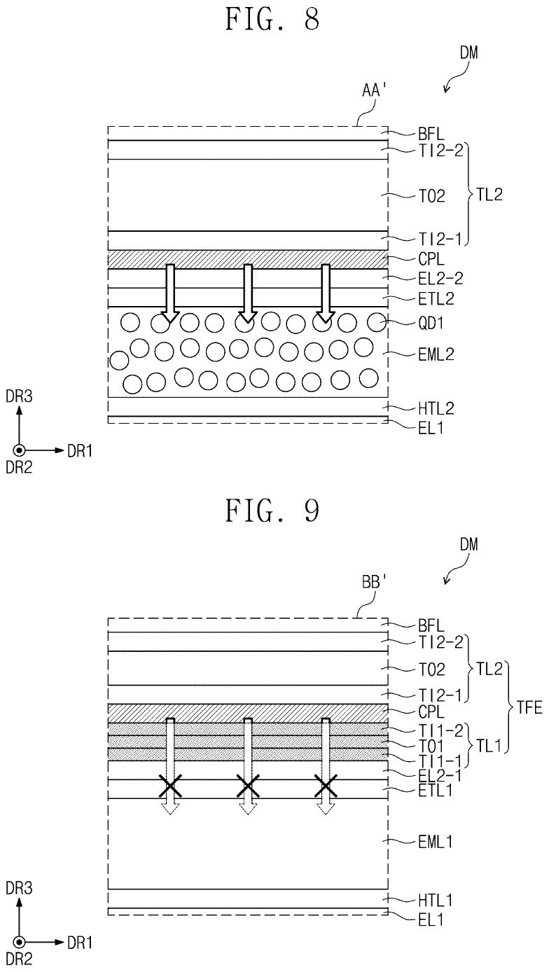

FIG. 8 is an enlarged view of area AA′ of FIG. 7.

Referring to FIG. 8, the second encapsulation portion TL2 may include a structure in which an inorganic layer/an organic layer are alternately laminated. For example, the second encapsulation portion TL2 may include a (2-1)^{th} inorganic encapsulation layer TI2-1, a second organic encapsulation layer TO2, and a (2-2)^{th} inorganic encapsulation layer TI2-2. However, an embodiment of the present disclosure is not limited to the illustration. For example, the second encapsulation portion TL2 may be provided as a glass substrate.

As an example, FIG. 8 illustrates that a capping layer CPL according to an embodiment includes the acidic resin material. However, a location of the acidic resin material is not limited to the illustration. For example, the display module DM may further include a resin layer (not illustrated) disposed between the capping layer CPL and the second encapsulation portion TL2 and including the “acidic resin material,” or the second organic encapsulation layer TO2 may include the “acidic resin material.”

For convenience of description, in FIG. 8, a path, along which the acidic resin material included in the capping layer CPL or hydrogen cations discharged from the acidic resin material permeate, is expressed by arrows.

The acidic resin material may be a polymer ink including a methacrylic acid, an acrylic acid, or a citric acid.

The “hydrogen cations” discharged from the acidic resin material may reduce a trap site of the quantum dot electroluminescence element. Accordingly, the brightness, the lifetime, and the reliability of the quantum dot light emitting element may be improved.

FIG. 8 illustratively illustrates that the acidic resin material permeates into the second light emitting element OLED-2, but this description may be applied to the third light emitting element OLED-3 (see FIG. 7) in the same and/or similar manner, and a duplicated description thereof will be omitted.

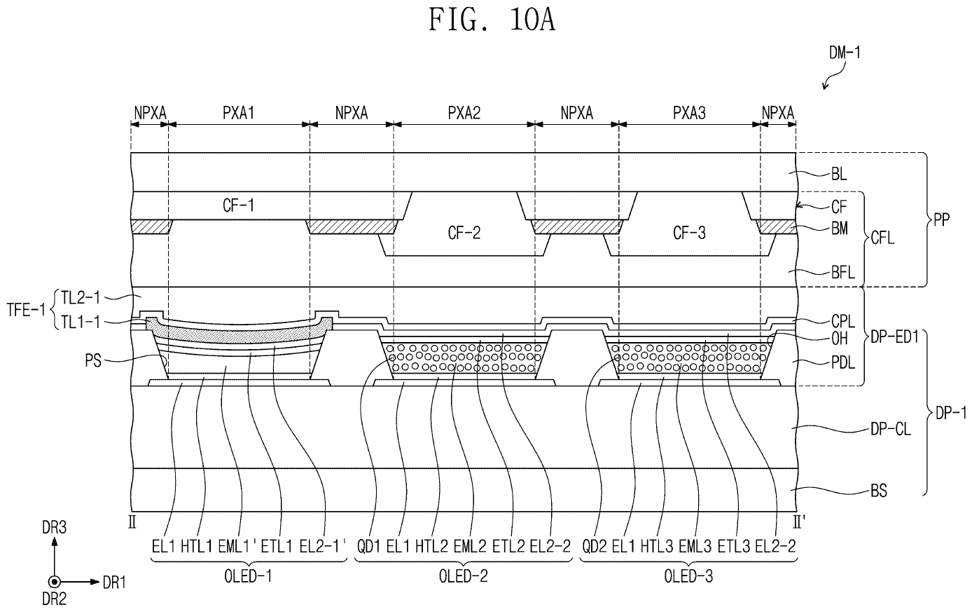

FIG. 9 is an enlarged view of area BB′ of FIG. 7.

Referring to FIG. 9, the first encapsulation portion TL1 may be disposed between the capping layer CPL and the first light emitting element OLED-1 (see FIG. 7). The first encapsulation portion TL1 may cover the first light emitting element OLED-1. A portion of the first encapsulation portion TL1 may be in contact with the pixel definition layer PDL. The other portion of the first encapsulation portion TL1 may cover the first light emitting element OLED-1.

The first encapsulation portion TL1 may include a structure in which an inorganic layer/an organic layer are alternately laminated. For example, the first encapsulation portion TL1 may include a (1-1)^{th} inorganic encapsulation layer TI1-1, a first organic encapsulation layer TO1, and a (1-2)^{th} inorganic encapsulation layer TI1-2.

The first encapsulation portion TL1 may function to block a path along which the acidic resin material and the hydrogen cations discharged from the capping layer CPL reaches the first light emitting element OLED-1. FIG. 9 illustrates a permeation path of the acidic resin material and the hydrogen cation with an arrow and illustratively illustrates that the permeation path is blocked by the first encapsulation portion TL1.

The first encapsulation portion TL1 may selectively encapsulate the first light emitting element OLED-1 among the light emitting elements OLED-1, OLED-2, and OLED-3 to effectively prevent the first light emitting element OLED-1 from being damaged by an acidic material. For example, the first light emitting layer EML1 or the first electron transport layer ETL1 included in the first light emitting element OLED-1 may be effectively prevented from being damaged by an acidic material. Accordingly, the brightness, the lifetime, and the reliability of the organic light emitting element OLED-1 may be improved.

FIGS. 7 to 9 illustratively illustrate that the display module DM has a “rear light emitting structure” as an example, but an embodiment of the present disclosure is not limited to the illustration. For example, the display module DM according to the present disclosure may have a “reverse light emitting structure.” The second electrodes EL2-1 and EL2-2 may be anodes, and the first electrode EL1 may be a cathode. Further, positions of the electron transport layers ETL1 and ETL2 and the hole transport layers ETR1 and ETR2 may be defined opposite to each other.

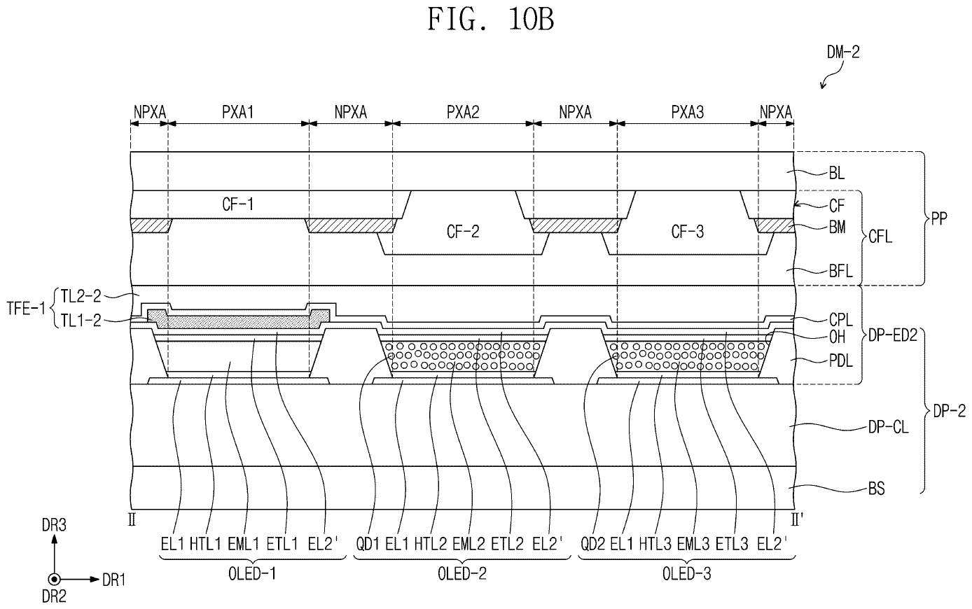

FIG. 10A is an enlarged cross-sectional view of the display module according to an embodiment of the present disclosure.

The components identical/similar to those described with reference to FIGS. 1 to 9 are designated by the identical/similar reference numerals, a duplicated description thereof will be omitted, and differences therebetween will be mainly described.

A display module DM-1 according to an embodiment may include the optical panel PP and a display panel DP-1 disposed under the optical panel PP.

In an embodiment, an upper surface of a first light emitting layer EML1′ may have a shape that is concave in a direction toward the base layer BS. The first light emitting layer EML1′ may be partially raised along a side surface PS of the pixel definition layer defining the pixel opening OH. For example, an ink provided to form the first light emitting layer EML1′ may be raised by a capillary phenomenon along the side surface PS of the pixel definition layer PDL.

Accordingly, the components arranged on the first light emitting layer EML1′ may have a curved shape according to the shape of the first light emitting layer EML1′. For example, a first electron transport layer ETL1′, a (2-1)^{th} electrode EL2-1′, and the first encapsulation portion TL1 may have a curved shape protruding toward the base layer BS.

FIG. 10B is an enlarged cross-sectional view of the display module according to an embodiment of the present disclosure.

The components identical/similar to those described with reference to FIGS. 1 to 9 are designated by the identical and/or similar reference numerals, a duplicated description thereof will be omitted, and differences therebetween will be mainly described.

A display module DM-2 according to an embodiment may include the optical panel PP and a display panel DP-2 disposed under the optical panel PP.

In an embodiment, a second electrode EL2′ may be provided as a common layer in all of a first light emitting element OLED-1′, a second light emitting element OLED-2′, and a third light emitting element OLED-3′. Accordingly, time and/or costs of a manufacturing process may be reduced compared to the display module DM (see FIG. 7) described with reference to FIG. 7.

In this case, a first encapsulation portion TL1-2 may not be in contact with the pixel definition layer PDL. The first encapsulation portion TL1-2 may be spaced apart from the pixel definition layer PDL with the second electrode EL2′ interposed therebetween.

However, a planar area of the first encapsulation portion TL1-2 may be larger than a planar area of the first light emitting layer EML1. Further, the planar area of the first encapsulation portion TL1-2 may be larger than a planar area of the first light emitting area PXA1. Accordingly, all paths along which the acidic resin material reaches the first light emitting element OLED-1′ in the third direction DR3 may be blocked. Thus, degradation of reliability of the first light emitting element OLED-1′ due to the acidic resin material may be prevented.

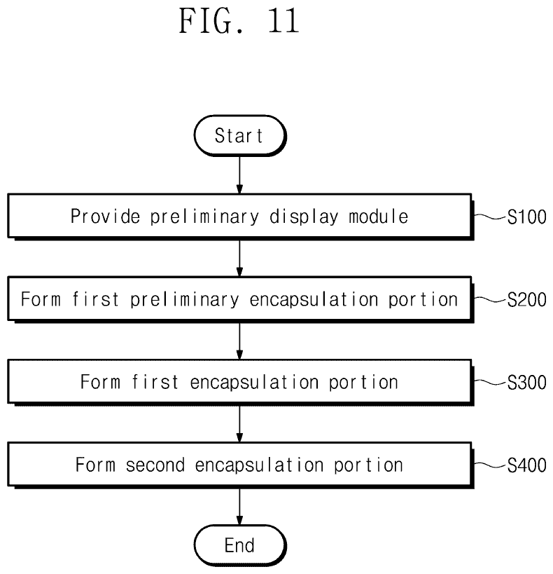

FIG. 11 is a flowchart of a method of manufacturing an electronic device according to an embodiment of the present disclosure.

A method of manufacturing an electronic device according to an embodiment may include an operation S100 of providing a preliminary display module including a base layer and a display element layer including a pixel definition layer which is disposed on the base layer and in which pixel openings are defined, and a first light emitting element, a second light emitting element, and a third light emitting element arranged in the pixel openings. An operation S200 of forming a first preliminary encapsulation portion overlapping the first light emitting element, the second light emitting element, and the third light emitting element on the pixel definition layer. An operation S300 of forming a first encapsulation portion by removing a portion of the first preliminary encapsulation portion, which overlaps the second light emitting element and the third light emitting element, An operation S400 of forming a second encapsulation portion overlapping the first light emitting element, the second light emitting element, and the third light emitting element and covering the first encapsulation portion.

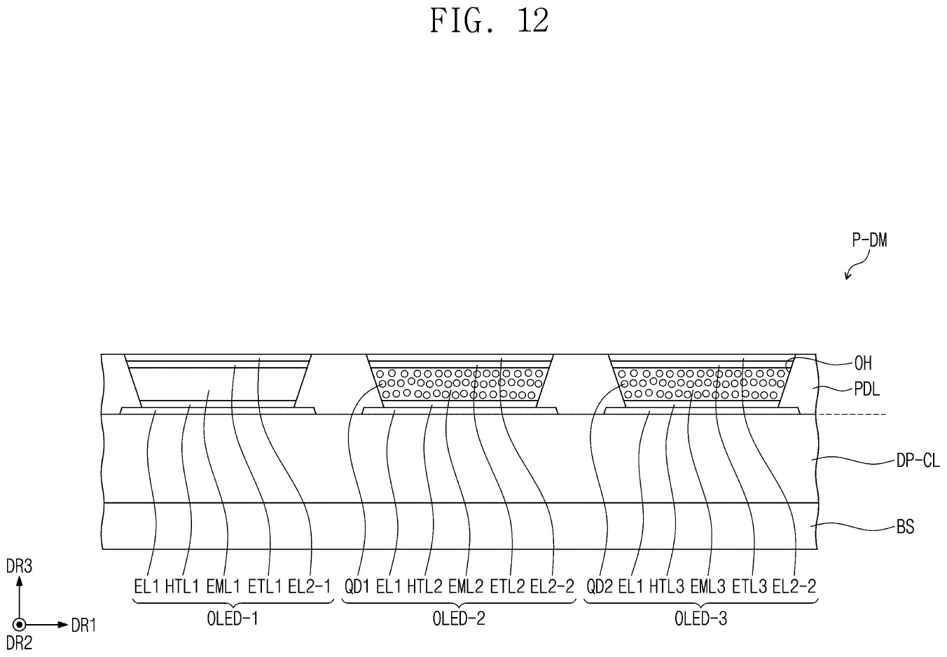

FIGS. 12 to 16 are views showing display modules for illustrating operations of the method of manufacturing an electronic device according to an embodiment of the present disclosure.

Referring to FIG. 12, the operation S100 (see FIG. 12) of providing the preliminary display module including the base layer and the display element layer including the pixel definition layer which is disposed on the base layer and in which pixel openings are defined, and the first light emitting element, the second light emitting element, and the third light emitting element arranged in the pixel openings may be performed.

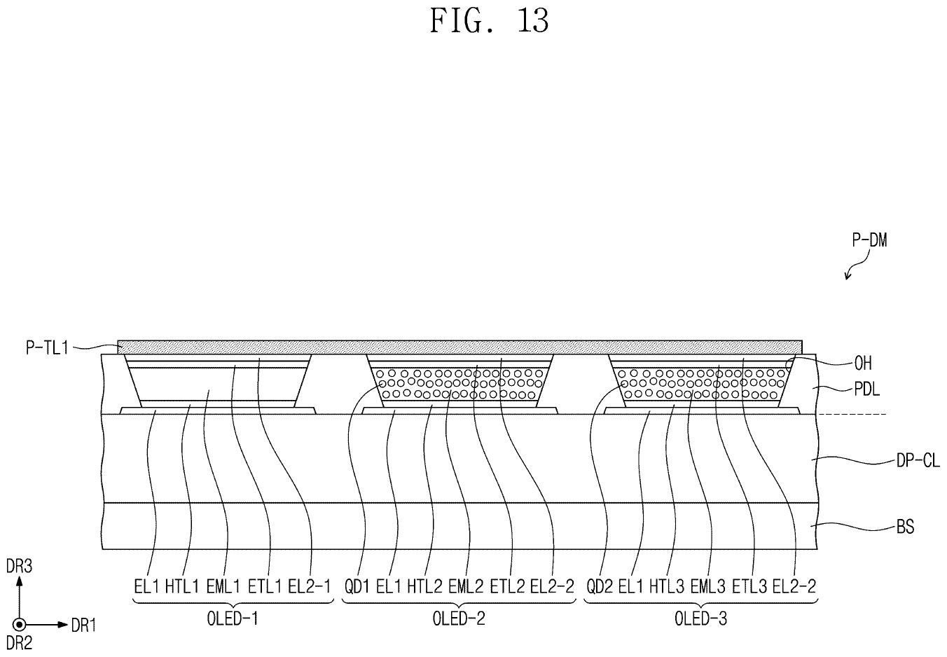

Thereafter, referring to FIG. 13, the operation S200 (see FIG. 12) of forming the first preliminary encapsulation portion overlapping the first light emitting element, the second light emitting element, and the third light emitting element on the pixel definition layer may be performed.

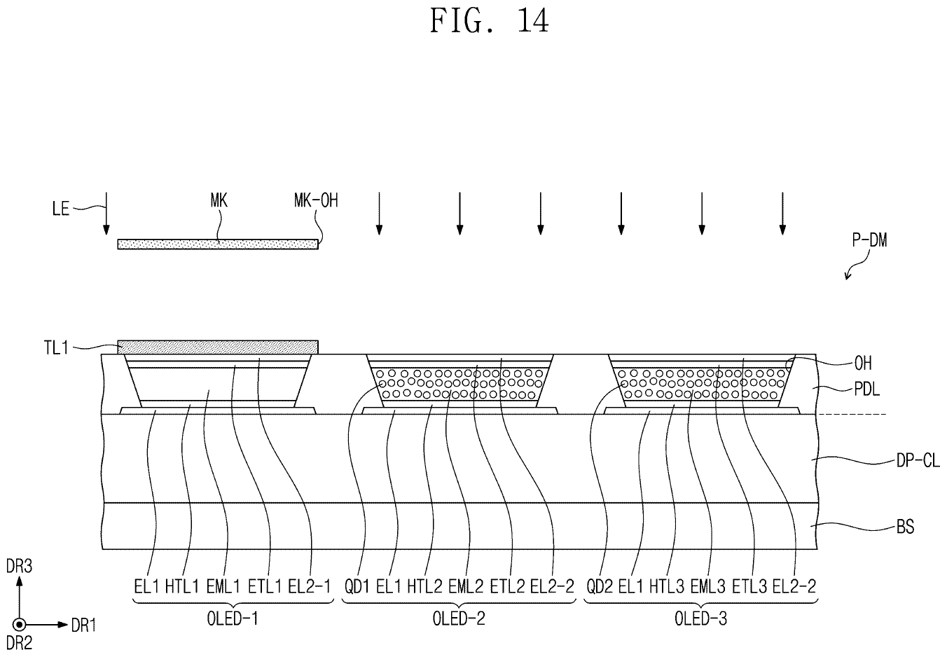

Thereafter, referring to FIG. 14, the operation S300 (see FIG. 12) of forming the first encapsulation portion by removing the portion of the first preliminary encapsulation portion, which overlaps the second light emitting element and the third light emitting element may be performed.

In an embodiment, the operation S300 (see FIG. 12) of forming the first encapsulation portion may include an operation of performing a photoresist process on the first preliminary encapsulation portion. For example, a process, in which a position in which the first encapsulation portion TL1 (see FIG. 7) is to be formed overlaps a mask MK, the other position overlaps a mask opening MK-OH included in the mask MK and a light LE is radiated, may be performed.

The method of manufacturing an electronic device according to an embodiment may further include an operation of forming a capping layer that covers the first encapsulation portion TL1, the pixel definition layer PDL, the second light emitting element OLED-2, and the third light emitting element OLED-3, after the operation S300 (see FIG. 12) of forming the first encapsulation portion.

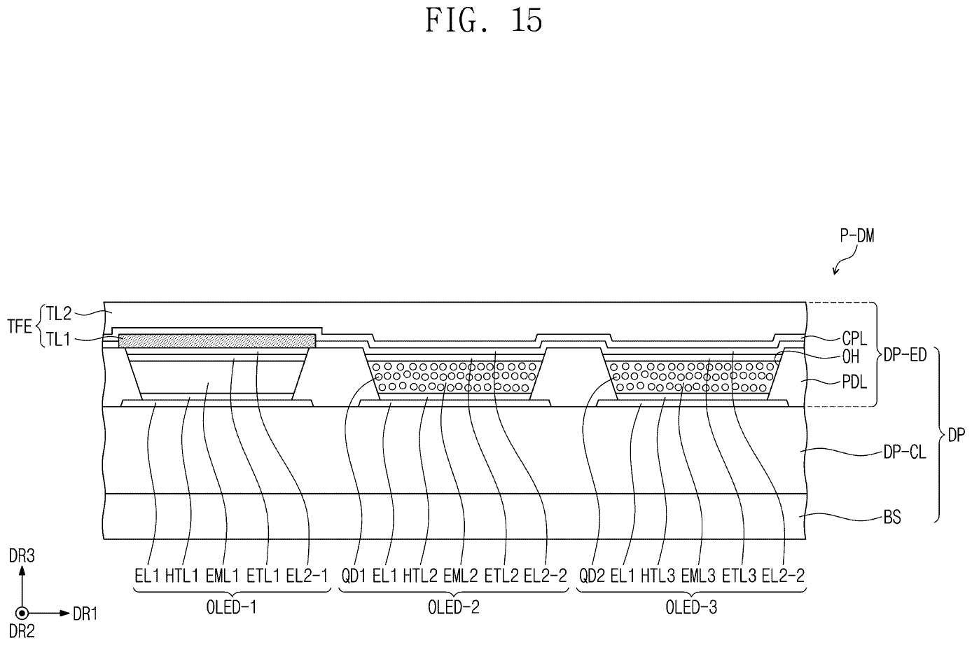

Thereafter, referring to FIG. 15, the operation S400 (see FIG. 12) of forming the second encapsulation portion overlapping the first light emitting element, the second light emitting element, and the third light emitting element and covering the first encapsulation portion may be performed.

However, an embodiment of the present disclosure is not limited to the illustration. For example, the method may further include, after the operation S300 of forming the first encapsulation portion, an operation S310 of forming the capping layer CPL (see FIG. 10) covering the first encapsulation portion TL1, the pixel definition layer PDL, the second light emitting element OLED-2, and the third light emitting element OLED-3 and an operation of forming the resin layer (not illustrated) including the acidic resin material on the capping layer CPL (see FIG. 10).

In an embodiment, the operation S400 of forming the second encapsulation portion may include an operation of alternately laminating an inorganic layer/an organic layer. For example, the operation S400 may include an operation of forming the (2-1)^{th} inorganic encapsulation layer TI2-1 (see FIG. 9) overlapping the first light emitting element OLED-1, the second light emitting element OLED-2, and the third light emitting element OLED-3, an operation of forming the second organic encapsulation layer TO2 (see FIG. 9) on the (2-1)^{th} inorganic encapsulation layer TI2-1 (see FIG. 9), and an operation of forming the (2-2)^{th} inorganic encapsulation layer TI2-2 (see FIG. 9) on the second organic encapsulation layer TO2 (see FIG. 9).

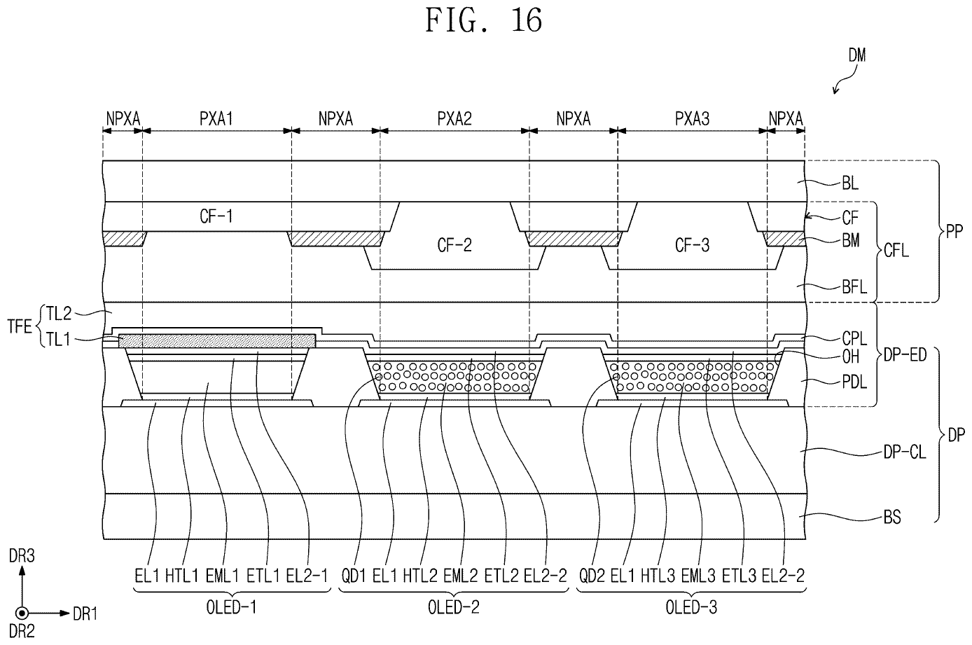

Thereafter, referring to FIG. 16, an operation of forming the optical panel PP on a preliminary display module P-DM may be performed. The optical panel PP may be directly formed on the display panel DP or may be formed separately and then bonded to the display panel DP.

According to the method of manufacturing an electronic device according to the present disclosure, a hybrid electronic device including all the organic light emitting element OLED-1 and the quantum dot light emitting elements OLED-2 and OLED-3 and having the improved brightness and the improved lifetime may be provided.

According to the present disclosure, a display module including both an organic light emitting element and a quantum dot light emitting element and thus having improved display quality may be provided.

Further, according to the present disclosure, a display module that selectively encapsulates only an organic light emitting element, positive ages a quantum dot light emitting element, and thus has improved reliability may be provided. Although the description has been made above with reference to examples of the present disclosure, it may be understood that those skilled in the art or those having ordinary knowledge in the art may variously modify and change the present disclosure without departing from the spirit and technical scope of the present disclosure described in the appended claims. Accordingly, the technical scope of the present disclosure is not limited to the detailed description of the specification. It should therefore be understood that the examples described above are exemplary in all respects and are not intended to be limiting.

What is claimed is:

1. A display module comprising:
a base layer;
a display element layer having a pixel definition layer disposed on the base layer, the pixel definition layer defining a plurality of pixel openings;
a first light emitting element, a second light emitting element, and the third light emitting element arranged in the plurality of pixel openings;
an encapsulation layer including a first encapsulation portion and a second encapsulation portion;
the first encapsulation portion is disposed on the pixel definition layer, wherein the encapsulation layer is overlapping the first light emitting element, and not overlapping the second light emitting element and the third light emitting element; and
the second encapsulation portion is disposed on the first encapsulation portion and overlapping the first light emitting element, the second light emitting element, and the third light emitting element.

2. The display module of claim 1, wherein the first light emitting element includes a first light emitting layer having an organic light emitting material,
wherein the second light emitting element includes a second light emitting layer having a first quantum dot, and
wherein the third light emitting element includes a third light emitting layer having a second quantum dot different from the first quantum dot.

3. The display module of claim 1, wherein the display element layer further comprises:
a capping layer covering the first encapsulation portion, the second light emitting element, and the third light emitting element; and
a resin layer disposed on the capping layer and wherein the resin layer includes an acidic resin material.

4. The display module of claim 1, wherein the display element layer further comprises:
a capping layer covering the first encapsulation portion, the second light emitting element, and the third light emitting element and wherein the capping layer includes an acidic resin material.

5. The display module of claim 1, wherein the first encapsulation portion further comprises: a (1-1)^{th} inorganic encapsulation layer, a first organic encapsulation layer, and a (1-2)^{th} inorganic encapsulation layer, and
wherein the second encapsulation portion includes a (2-1)^{th} inorganic encapsulation layer, a second organic encapsulation layer, and a (2-2)^{th} inorganic encapsulation layer.

6. The display module of claim 5, wherein the second organic encapsulation layer has an acidic resin material.

7. The display module of claim 5, wherein the acidic resin material includes any one of a methacrylic acid, an acrylic acid, or a citric acid.

8. The display module of claim 1, wherein the first light emitting element provides a blue light,
wherein the second light emitting element provides a red light, and
wherein the third light emitting element provides a green light.

9. The display module of claim 1, wherein the second encapsulation portion contains glass.

10. The display module of claim 1, wherein the first light emitting element further comprises a first hole transport layer, a first light emitting layer, and a first electron transport layer that are all sequentially laminated in a direction away from the base layer;
wherein the second light emitting element includes a second hole transport layer, a second light emitting layer, and a second electron transport layer that are all sequentially laminated in a direction away from the base layer, and
wherein the third light emitting element includes a third hole transport layer, a third light emitting layer, and a third electron transport layer that are all sequentially laminated in a direction away from the base layer.

11. The display module of claim 1, wherein the first light emitting element further comprises a first electrode, a first electron transport layer, a first light emitting layer, a hole transport layer and a (2-1)^{th} electrode that are all sequentially laminated in a direction away from the base layer;
wherein the second light emitting element includes the first electrode, a second electron transport layer, a second light emitting layer, the hole transport layer and a (2-2)^{th} electrode that are all sequentially laminated in a direction away from the base layer;
wherein the third light emitting element includes the first electrode, a third electron transport layer, a third light emitting layer, the hole transport layer and the (2-2)^{th} electrode that are all sequentially laminated in a direction away from the base layer;,
wherein a first portion of the first encapsulation portion covers the pixel definition layer, and
wherein a second portion of the first encapsulation portion covers the first light emitting element.

12. The display module of claim 1, wherein at least the first or the second portion of the first encapsulation portion is curved in a direction toward the base layer.

13. The display module of claim 1, wherein the first light emitting element further comprises a first electrode, a first light emitting layer, and a second electrode that are all sequentially arranged in a direction away from the base layer;
wherein the first encapsulation portion and the pixel definition layer are spaced apart from each other with the second electrode interposed therebetween; and
wherein the first encapsulation portion has a first encapsulation portion planar area and the first light emitting layer has a first light emitting layer planar area; and
the first encapsulation portion planar area is larger than the first light emitting layer planar area.

14. An electronic device comprising:
a display module having a base layer and a display element layer; the display element layer having a pixel definition layer which is disposed on the base layer, the pixel definition layer defining a plurality of pixel openings;
a first light emitting element, a second light emitting element, and the third light emitting element arranged in the plurality of pixel openings;
an encapsulation layer including a first encapsulation portion and a second encapsulation portion;
wherein, the first encapsulation portion is disposed on the pixel definition layer, overlapping the first light emitting element, and not overlapping the second light emitting element and the third light emitting element and
wherein, the second encapsulation portion is disposed on the first encapsulation portion and overlapping the first light emitting element, the second light emitting element, and the third light emitting element;
a housing configured to provide a base space in which the display module is to be disposed; and
an electronic module configured to provide an electrical signal to the display module.

15. A method of manufacturing an electronic device, comprises:
providing a preliminary display module having a base layer and a display element layer; the display element layer having a pixel definition layer disposed on the base layer, wherein the pixel definition layer defines a plurality of pixel openings, and a first light emitting element, a second light emitting element, and a third light emitting element arranged in the plurality of pixel openings;
forming a first preliminary encapsulation portion that overlaps the first light emitting element, the second light emitting element, and the third light emitting element on the pixel definition layer;
forming a first encapsulation portion by removing the first preliminary encapsulation portion that overlaps the second light emitting element and the third light emitting element; and
forming a second encapsulation portion that overlaps the first light emitting element, the second light emitting element, the third light emitting element, and the first encapsulation portion.

16. The method of claim 15, wherein the forming of the first encapsulation portion further comprises performing a photoresist process on the first preliminary encapsulation portion.

17. The method of claim 15, wherein the forming of the second encapsulation portion further comprises:
forming a (2-1)^{th} inorganic encapsulation layer that overlaps the first light emitting element, the second light emitting element, and the third light emitting element;
forming a second organic encapsulation layer on the (2-1)^{th} inorganic encapsulation layer;
forming a (2-2)^{th} inorganic encapsulation layer on the second organic encapsulation layer, and
wherein the second organic encapsulation layer has an acidic resin material.

18. The method of claim 15, further comprises:
after the forming of the first encapsulation portion forming a capping layer overlapping the first encapsulation portion, the pixel definition layer, the second light emitting element, and the third light emitting element; and
wherein the capping layer has an acidic resin material.

19. The method of claim 15, further comprises:
after the forming of the first encapsulation portion,
forming a capping layer overlapping the first encapsulation portion, the pixel definition layer, the second light emitting element, and the third light emitting element; and
forming a resin layer, having an acidic resin material, onto the capping layer.

20. The method of claim 15, wherein the second encapsulation portion is a glass substrate,
wherein the first light emitting element is an organic light emitting element, and
wherein the second light emitting element and the third light emitting element are quantum dot light emitting elements.
